(19) United States
(12) Patent Application Publication
(10) Pub. No.: US 2019/0108996 A1
(43) Pub. Date: Apr. 11, 2019

(54) METHOD OF PRODUCING LIQUID CRYSTAL PANEL

(71) Applicant: SHARP KABUSHIKI KAISHA, Osaka (JP)

(72) Inventor: KOHSHIROH TANIIKE, Sakai City (JP)

(21) Appl. No.: 16/155,614

(22) Filed: Oct. 9, 2018

(30) Foreign Application Priority Data
Oct. 11, 2017 (JP) 2017-197405

(51) Int. Cl. H01L 21/02; H01L 21/67; B08B 3/04

(52) U.S. Cl. CPC H01L 21/02054; B08B 3/04; H01L 21/67057

(57) ABSTRACT

A method of producing a liquid crystal panel includes a first dry-cleaning process of dry cleaning a glass substrate for a liquid crystal panel, a wet-cleaning process of wet cleaning the glass substrate after the first dry-cleaning process, and a second dry-cleaning process of dry cleaning the glass substrate after the wet-cleaning process.

### CROSS REFERENCE TO RELATED APPLICATION

This application claims priority from Japanese Patent Application No. 2017-197405 filed on Oct. 11, 2017. The entire contents of the priority application are incorporated herein by reference.

### TECHNICAL FIELD

The technology described herein relates to a method of producing a liquid crystal panel.

### BACKGROUND

An example of the method of cleaning a glass substrate for a liquid crystal panel is described in Japanese Unexamined Patent Application Publication No. 11-176794. In such a cleaning method, a glass substrate for a liquid crystal panel is cleaned by wet cleaning using a cleaning liquid. The cleaning improves film-formation acceptability of the glass substrate.

The wet cleaning has a low ability to remove foreign substances and provides low wettability to the cleaned surface of the substrate. To solve the problems, a treatment agent is added to the cleaning liquid to make the contact angle of the substrate smaller or a silane coupling agent is used to improve the adhesion of the film to the surface of the substrate. This improves the film formation acceptability of the substrate. However, the employment of such agents increases the ion density of the surface of the substrate in some cases due to the effect (elution) of the added agents. In such a case, a liquid-crystals holding rate may be lowered, leading to a decrease in reliability (specifically described, the substrate may have unevenness and stains when subjected to a long-term aging test or stored for a long-time period).

### SUMMARY

The technology described herein was made in view of the above-described circumstance and an object thereof is to provide a method of producing a liquid crystal panel in which film-formation acceptability of a glass substrate is improved.

To solve the above-described problem, a method of producing a liquid crystal panel according to the technology described herein includes a first dry-cleaning process of dry cleaning a glass substrate for a liquid crystal panel, a wet-cleaning process of wet cleaning the glass substrate after the first dry cleaning process, and a second dry-cleaning process of dry cleaning the glass substrate after the wet-cleaning process.

The dry cleaning (first dry-cleaning process) makes the contact angle of the glass substrate smaller, allowing the cleaning liquid to spread over the glass substrate during the wet cleaning. This allows the wet cleaning to more reliably remove foreign substances. Furthermore, during formation of a film on the glass substrate after the second dry-cleaning process, the smaller contact angle of the glass substrate allows the solution containing a film forming material to spread over the glass substrate, i.e., the substrate has higher film-formation acceptability. After the dry cleaning, the contact angle of the glass substrate increases with time. If the method does not include the second dry-cleaning process, after the first dry-cleaning process, the contact angle of the glass substrate increases by a value corresponding to the duration of the wet-cleaning process. This lowers the film-formation acceptability. In the above-described method, the additional dry cleaning (second dry-cleaning process) after the wet-cleaning process allows the glass substrate to move on to the next process while keeping the low contact angle.

The technology described herein improves the film-formation acceptability of the glass substrate.

### BRIEF DESCRIPTION OF THE DRAWINGS

FIG. 1 is a cross-sectional view illustrating a liquid crystal display device according to one embodiment of the technology described herein taken in the longitudinal direction (Y-axis direction).

FIG. 2 is a side view illustrating a substrate treatment apparatus.

FIG. 3 is a diagram indicating cleaning effects on a glass substrate.

FIG. 4 is a graph indicating relationship between elapsed times and substrate contact angles.

### DETAILED DESCRIPTION

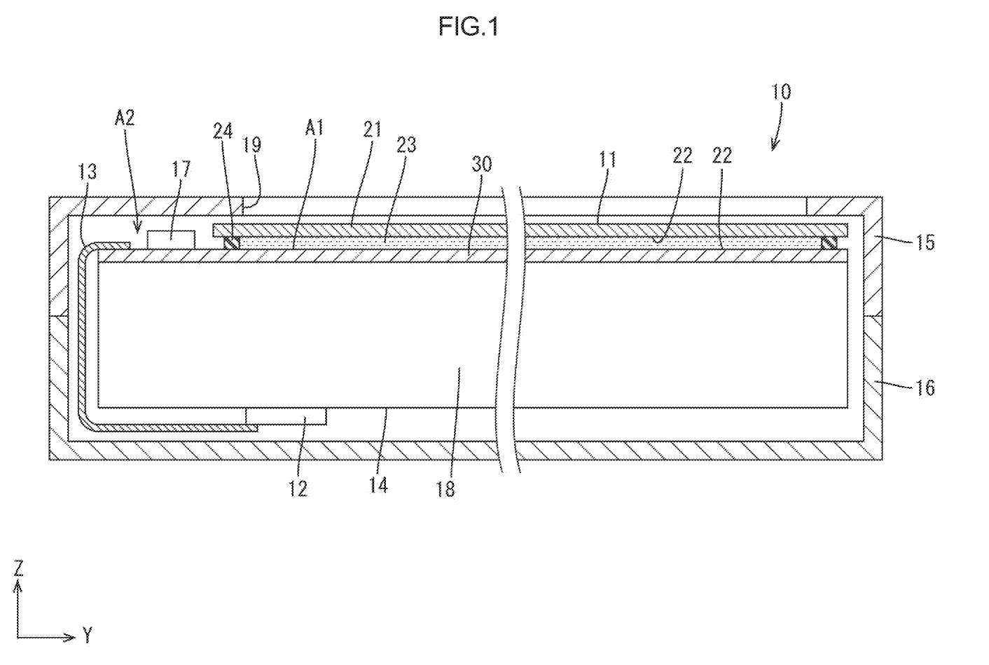

One embodiment according to the technology described herein will be described with reference to FIGS. 1 to 4. As illustrated in FIG. 1, a liquid crystal display device 10 according to the embodiment includes a liquid crystal panel 11 (display panel), a control circuit board 12 (external signal supply source) configured to supply various input signals to a driver 17 included in the liquid crystal panel 11, a flexible board 13 (external connection member) electrically connecting; the liquid crystal panel 11 with the external control circuit board 12, and a backlight unit 14 (lighting unit), which is an external light source configured to apply light to the liquid crystal panel 11. As illustrated in FIG. 1, the backlight unit 14 includes a box-like chassis 18 having an opening at the front side (side adjacent to the liquid crystal panel 11), a light source (not illustrated) (such as a cold-cathode tube, an LED, and an organic EL) in the chassis 18, and an optical member (not illustrated) covering the opening of the chassis 18. The optical member has a function of converting light from the light source into planar light, for example. The liquid crystal panel 11 has a display area A1 in which an image is displayed and a non-display area A2 surrounding the display area A1.

As illustrated in FIG. 1, the liquid crystal display device 10 includes front and rear exterior members 15 and 16 that enclose the liquid crystal panel 11 and the backlight unit 14, which are fitted together. The front exterior member 15 has an opening 19 through which an image displayed in the display area A1 of the liquid crystal panel 11 is viewable from the outside. The liquid crystal display device 10 according to the embodiment may be used in various electronic devices (not illustrated), such as a mobile phone (including a smart phone), a laptop computer (including a tablet computer), a wearable device (including a smart watch), a mobile terminal device (including an electronic book and a PDA), a portable video game player, and a digital photo frame.

As illustrated in FIG. 1, the liquid crystal panel 11 includes two substrates 21 and 30 opposed to each other, a liquid crystal layer 23 (medium layer) sandwiched between the two substrates 21 and 30 and including liquid crystal molecules, which are substances whose optical properties are changed by application of an electrical field, and a sealing member 24 sandwiched between the two substrates 21 and 30 and surrounding the liquid crystal layer 23 to seal the liquid crystal layer 23. One of the substrates 21 and 30 that is on the front side (front surface side, upper side in FIG. 1) is a CF substrate 21 (counter substrate) and the other on the rear side (rear surface side) is an array substrate 30 (active matrix substrate, device side substrate). The liquid crystal molecules in the liquid crystal layer 23 are horizontally-aligned liquid crystal molecules, for example, but not limited to the horizontally-aligned liquid crystal molecules. Furthermore, polarizing plates (not illustrated) are attached to outer surfaces of the substrates 21 and 30. The CF substrate 21 includes a glass substrate having a color filter and an overcoat film (both not illustrated) on its inner surface (surface adjacent to the liquid crystal layer 23). The color filter includes color portions (not illustrated) in three colors of R (red), G (green), and B (blue) arranged in a matrix. The color portions face respective pixels of the array substrate 30.

The array substrate 30 includes a glass substrate having various films formed by photolithography on its inner surface. The array substrate 30 mainly includes TFTs, pixel electrodes, and common electrodes facing the pixel electrodes (all not illustrated). A driver 17 configured to drive the liquid crystal panel 11 1s disposed on an end of the array substrate 30. Alignment films 22, 22 are disposed on surfaces of the CF substrate 21 and the array substrate 30 adjacent to the liquid crystal layer 23. Specifically described, the alignment film 22 on the CF substrate 21 is disposed on the surface of the glass substrate included in the CF substrate 21 (for example, on the surface of the overcoat film) and the alignment film 22 on the array substrate 30 is disposed on the surface of the glass substrate included in the array substrate 30 (for example, on the surfaces of the common electrodes). However, the arrangement of the alignment films 22 is not limited to the above. Examples of the material of the overcoat film include, but are not limited to, polyimide, an acrylic resin, and an epoxy resin. The overcoat film may be an inorganic protective film, such as a nitride film and an oxide film. Examples of the material of the common electrode include, but are not limited to, a transparent electrode material, such as indium tin oxide (ITO) and indium zinc oxide (IZO).

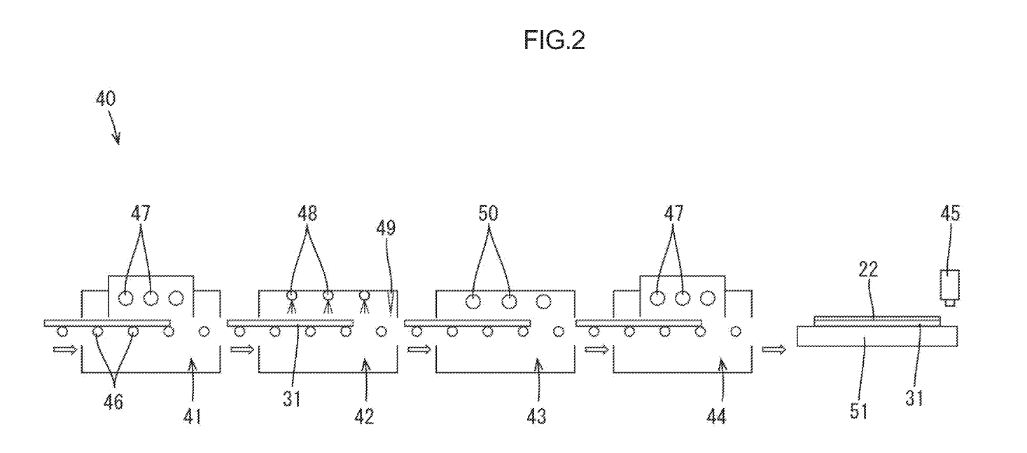

In the production process of the liquid crystal panel 11, the surface of the glass substrate is cleaned before the alignment film is formed on the glass substrate. FIG. 2 illustrates an example of a substrate treatment apparatus 40 for producing a glass substrate 31 to be included in the liquid crystal panel 11 (display panel). The substrate treatment apparatus 40 includes treatment tanks 41, 42, 43, and 44 in which the glass substrate 31 Is cleaned, an alignment film applicator 45 configured to form the alignment film 22 on the surface of the glass substrate 31, multiple rollers 46 configured to transport the glass substrate 31 in the treatment tanks 41, 42, 43, and 44. The substrate treatment apparatus 40 further includes a stage 51 on which the glass substrate 31 is placed during formation of the alignment film 22 on the glass substrate 31. The substrate treatment apparatus 40 further includes an unloader and a robotic arm (not illustrated) configured to move the glass substrate 31 from the treatment tank 44 to the stage 51. The stage 51 is formed of casting metal, for example, and the surface thereof is coated with fluorine, for example, for antistatic.

In the treatment tank 41, discharge lamps 47 configured to emit excimer UV to the glass substrate 31 are disposed. This enables the glass substrate 31 to be dry cleaned with excimer UV in the treatment tank 41. In the treatment tank 42, the glass substrate 31 is wet cleaned. In the treatment tank 42, cleaning liquid dispensers 48 and an air knife 49 are disposed. The cleaning liquid dispensers 48 are configured to eject a cleaning liquid onto the glass substrate 31. The air knife 49 is configured to spray highly-pressurized air (compressed air) to the surface of the glass substrate 31 to blow the cleaning liquid away. The cleaning liquid dispensers 48 may be any one of a line shower, a cavitation jet nozzle, a megasonic device-attached water jet nozzle, and any combination thereof, for example. Examples of the cleaning liquid include, but are not limited to, pure water and ultra-pure water. The cleaning liquid may be an alkali chemical.

In the treatment tank 43, IR heaters 50 are disposed to dry the glass substrate 31. In the treatment tank 44, discharge lamps 47 configured to emit excimer UV to the glass substrate 31 are disposed. This enables the glass substrate 31 to be dry cleaned with excimer UV in the treatment tank 44. The dry cleaning is not limited to the dry-cleaning method using excimer UV and may be one using atmospheric-pressure plasma. The dry cleaning using atmospheric-pressure plasma Is more preferable than the dry cleaning using excimer UV, because the dry cleaning using atmospheric-pressure plasma is less likely to damage the glass substrate 31 (the overcoat film, for example). The alignment film applicator 45 is configured to form alignment films by an inkjet method, for example. The alignment film applicator 45 is configured to continuously eject liquid droplets for forming an alignment film onto the glass substrate 31 while moving over the glass substrate 31.

Next, a method of producing the liquid crystal panel 11 Is described. The method of producing the liquid crystal panel 11 includes a structure formation process (photolithography process), a cleaning process, an alignment film formation process, a substrate bonding process, and a polarizing plate attachment process. In the structure formation process, various metal films or insulating films are formed on the inner surfaces of glass substrates, which constitute the CF substrate 21 and the array substrate 30, by photolithography to form various structures. In the cleaning process, the inner surfaces of the CF substrate 21 and the array substrate 30 (surfaces of the glass substrates 31), which are adjacent to the liquid crystal layer, are cleaned. In the alignment film formation process, alignment films are formed on the inner surfaces of the CF substrate 21 and the array substrate 30, which are adjacent to the liquid crystal layer. In the substrate bonding process, the CF substrate 21 and the array substrate 30 are bonded together with the liquid crystal layer 23 therebetween. In the polarizing plate attachment process, polarizing plates are attached to the outer surfaces of the CF substrate 21 and the array substrate 30. In the following description, the cleaning process and the alignment film formation process are described in detail.

A method of cleaning the glass substrate 31 (a glass substrate for a liquid crystal panel) in the cleaning process of the embodiment includes a first dry-cleaning process of dry cleaning the glass substrate 31, a wet-cleaning process of wet cleaning the glass substrate 31 after the first dry-cleaning process, and a second dry-cleaning process of dry cleaning the glass substrate 31 after the wet-cleaning process.

(First Dry-Cleaning Process)

In the first dry-cleaning process, the discharge lamps 47 emit excimer UV to the glass substrate 31 transported by the rollers 46 to the treatment tank 41 in FIG. 2.

(Wet-Cleaning Process)

In the wet-cleaning process, the glass substrate 31 transported by the rollers 46 to the treatment tank 42 is wet cleaned. Specifically described, line shower cleaning, cavitation jet cleaning, and megasonic cleaning are sequentially performed, for example, by using the cleaning liquid dispensers 48.

(Drying Process)

After the wet-cleaning process, a drying process is performed in the treatment tank 43 by using the IR heater 50.

(Second Dry-Cleaning Process)

In the second dry-cleaning process, the discharge lamps 47 emit excimer UV to the glass substrate 31 transported by the rollers 46 to the treatment tank 44.

(Alignment Film formation Process)

In the alignment film formation process, the alignment film applicator 45 (nozzle head) ejects a solution, which includes an alignment film material (polyimide, for example), in a form, of liquid droplets onto the surface of the cleaned glass substrate 31 (ink-jet method). The droplets on the glass substrate 31 spread to be united together and become a film. Then, the film is subjected to drying treatment (preliminary baking and main baking) and alignment treatment using a rubbing technique to form the alignment film 22. In an example illustrated in FIG. 2, the alignment film applicator 45 is moved relative to the stage 51 from the left to the right in FIG. 2 to form a film on the surface of the glass substrate 31. However, the stage 51 may be moved relative to the alignment film applicator 45. Furthermore, the method of forming a film on the glass substrate 31 is not limited to the above-described inkjet method and may be a roll coater method using a flexographic printing plate, for example. When the glass substrate 31 (mother glass) is small, the roll coater method is likely to be employed. When the glass substrate 31 is large, the Inkjet method Is likely to be employed. The size of the flexographic printing plate increases as the size of the glass substrate 31 increases, lowering the printing precision due to a larger degree of expansion and contraction of the flexographic printing plate. The alignment treatment process is not limited to the rubbing technique and may be any one of various photoalignment processes in which the film is exposed to polarized light. The photoalignment process may be performed after the preliminary baking and before the main baking or may be performed after the main baking. The timing of the photoalignment process is not limited to the above.

Next, effects of the embodiment are described. In this embodiment, the contact angle of the glass substrate 31 is made smaller (wettability is made higher) by the dry cleaning (first dry-cleaning process), allowing the cleaning liquid to spread over the glass substrate 31 in the wet cleaning. This enables foreign substances to be more reliably removed in the wet cleaning. Furthermore, the smaller contact angle of the glass substrate 31 allows the solution containing a film forming material to spread over the glass substrate during formation of a film on the glass substrate 31 after the second dry-cleaning process, improving film-formation acceptability. Specifically described, the solution constituting the alignment film 22 is able to spread over the glass substrate 31, and thus formability of the alignment film 22 is improved.

Furthermore, the dry cleaning using excimer UV decomposes the contaminant such as an organic substance on the surface of the glass substrate 31, and the decomposed materials are oxidized and removed by active oxygen generated by application of the excimer UV. The dry cleaning may use atmospheric-pressure plasma. In such a case, the contaminant such as an organic substance on the surface of the glass substrate 31 is removed by the use of the atmospheric-pressure plasma.

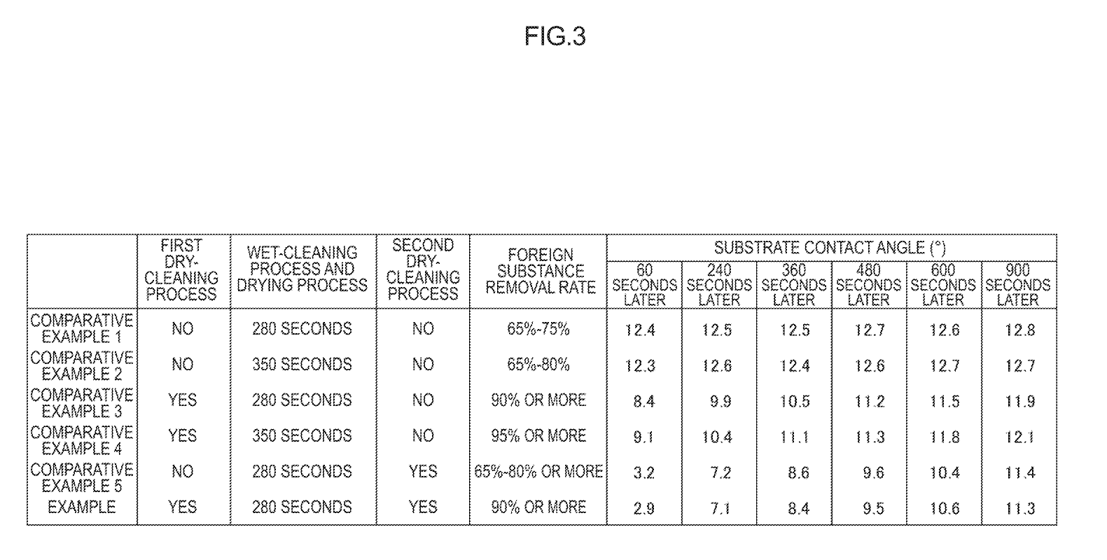

FIG. 3 indicates contaminant removal rates determined after the cleaning process on the surface (on which an alignment film is formed) of the glass substrate 31 to be included in the CF substrate 21 and contact angles between water and the substrate determined after the cleaning process, for example. In the comparative examples 1 and 2 in FIG. 3, the wet-cleaning process and the drying process were performed without the first and second dry-cleaning process. In the comparative examples 3 and 4 in FIG. 3, the wet-cleaning process and the drying process were performed without the second dry-cleaning process. In the comparative example 5 in FIG. 3, the wet-cleaning process and the drying process were performed without the first dry-cleaning process. In each of the first and second dry-cleaning process, the dry cleaning was performed for 20 seconds. The phrase “without the first (or second) dry-cleaning process” means that the glass substrate 31 passed through the treatment tank 41 (or the treatment tank 44) with the discharge lamps 47 being turned off.

The third row from the left (wet-cleaning process and drying process) in FIG. 3 indicates the total times of the wet-cleaning process and the drying process. The duration of the drying process is the same for. the comparative examples 1 to 5 and the example. In other words, the wet cleaning in the comparative example 2 is longer than that in the comparative example 1 by 70 seconds. Foreign substance removal rates in FIG. 3 were obtained by (the number of foreign substances before cleaning—the number of foreign substances after cleaning)/the number of foreign substances before cleaning (%). The number of foreign substances before cleaning is the number of foreign substances found on the surface of the glass substrate 31 before cleaning. The number of foreign substances after cleaning is the number of foreign substances found on the cleaned surface of the glass substrate 31. The substrate contact angles in FIG. 3 were determined predetermined time periods later from a reference time (0 second) that is when the glass substrate 31, which is transported by the rollers 46, was moved out of the treatment tank 44 (the end of the second dry-cleaning process). In the comparative examples 1 to 5 and the example, the substrate contact angles before cleaning are in a range of 20° to 30°. The inventor of this application has confirmed that variations in the substrate contact angles before cleaning in this range have little influence on the substrate contact angles after cleaning.

Referring to foreign substance removal rates of the

comparative examples 1 to 3, the foreign substance removal rate is higher in the comparative example 3, in which the dry cleaning was performed for 20 seconds before the wet-cleaning process, than in the comparative example 2, in which the duration of the wet cleaning was longer than that in the comparative example 1 by 70 seconds. Furthermore, comparison between the comparative example 3 and the example reveals that the substrate contact angles after the cleaning were made smaller by the second dry-cleaning process. Furthermore, as indicated in FIG. 3, after the dry cleaning, the contact angle of the glass substrate 31 increases with time. Thus, when the second dry-cleaning process is not performed, after the first dry-cleaning process, the contact angle of the glass substrate during the alignment film formation increases by a value corresponding to the duration of the wet-cleaning process, lowering the film-formation acceptability. In this embodiment, since the dry cleaning (second dry-cleaning process) is performed again after the wet-cleaning process, the glass substrate 31 is able to move on to the next alignment film formation process while keeping the low contact angle. In other words, the second dry-cleaning process reduces an increase in the substrate contact angle caused by the increased duration of the wet-cleaning, enabling the duration of the wet cleaning to be longer. This further increases the foreign substance removal rates.

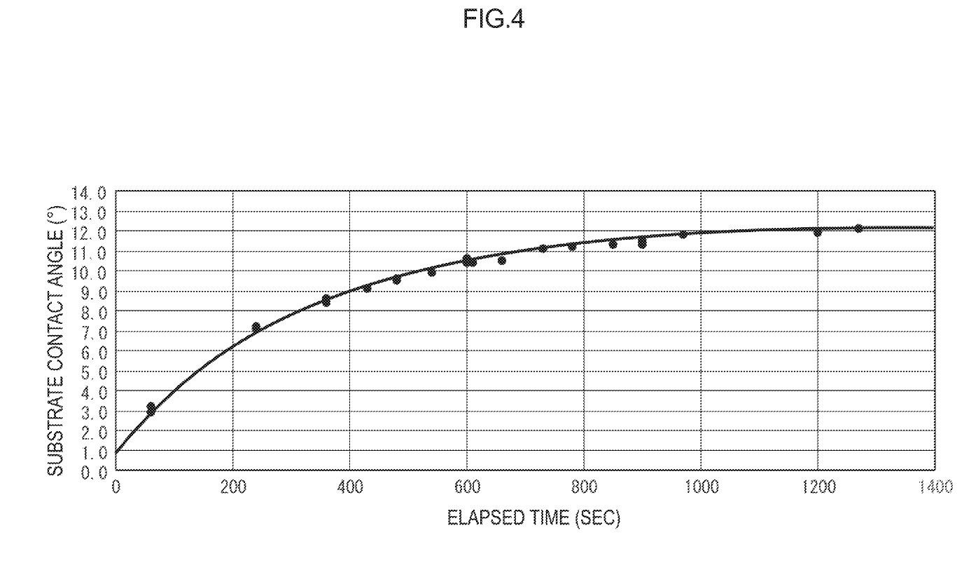

Next, with respect to the glass substrate 31, FIG. 4 indicates a correlation between the time elapsed from the end of the dry cleaning and the substrate contact angle. The horizontal axis of the graph in FIG. 4 indicates the time elapsed from the end of the dry cleaning and the vertical axis indicates the substrate contact angles of the glass substrate 31. FIG. 4 was made based on the measurement results of the comparative examples 3 to 5 and the example in FIG. 3. The contact angles of the substrate in FIG. 3 were determined using the timing of when the glass substrate 31 was moved out of the treatment tank 44 as a reference time. The contact angles in FIG. 4 were determined using the end of the last dry cleaning as the reference. Specifically described, in the graph in FIG. 4, the comparative examples 3 and 4 use the end of the first dry-cleaning process as the reference point of the elapsed time, and the comparative example 5 and the example uses the end of the second dry-cleaning process (the timing of when the substrate 31 was moved out of the treatment tank 44) as the reference point of the elapsed time.

For example, in the comparative example 3 in FIG. 3, after the first dry-cleaning process, the wet-cleaning process and the drying process took 280 seconds and the process of passing through the treatment tank 44 with the switched-off discharge lamps 47 took 20 seconds. Referring to FIG. 3, In the comparative example 3, the substrate contact angle determined 60 seconds later from when the substrate 31 was moved out of the treatment tank 44 is 8.4% for example. Specifically described, in the comparative example 3, the substrate contact angle determined 360 seconds (280 seconds+20 seconds+60 seconds) later from the last dry cleaning (first dry-cleaning process) is 8.4°. The graph in FIG. 4 uses the values obtained as above.

As indicated in FIG. 4, the substrate contact angle increases with time at a relatively high rate immediately after the end of the dry cleaning, and then increases at a lower rate. The contact angle of the glass substrate exceeds 10° when 600 seconds passed from the end of the dry cleaning as indicated in FIG. 4. The inventor of the present application found that the alignment film 22 would have a pinhole in such a case. More specifically described, the defect rate of the alignment film significantly increases and exceeds 1% when 600 seconds passed from the end of the dry cleaning. The present embodiment performs the alignment film formation process within 600 seconds from the end of the second dry-cleaning process to more reliably reduce the possibility that the alignment film 22 will have a pinhole. More specifically described, it is preferable that liquid droplets for forming an alignment film are discharged from the alignment film applicator 45 onto the glass substrate 31 within 600 seconds from the end of the dry cleaning in the treatment tank 44 (end of the second dry-cleaning process).

Furthermore, the inventor of the present, application found that, when the substrate contact angle is smaller than 7°, the liquid crystal display device 10 is able to have a display quality that does not allow the brightness defect, in the alignment film caused by the pinhole to be recognized, if including an ND filter, and when the substrate contact angle is smaller than 5°, the liquid crystal display device 10 is able to have a display quality that does not allow the brightness defect in the alignment film caused by the pinhole to be recognized, without an ND film, at a higher brightness. As can be seen from FIG. 4, when the liquid droplets for forming an alignment film are discharged from the alignment film applicator 45 onto the glass substrate 31 within 240 seconds from the end of the dry cleaning, the substrate contact angle during the formation of the alignment film 22 is smaller than 7°, and when the liquid droplets for forming an alignment film are discharged from the alignment film applicator 45 onto the glass substrate 31 within 150 seconds from the end of the dry cleaning, the substrate contact angle during the formation of the alignment film 22 is smaller than 5°.

### Other Embodiments

The technology described herein is not limited to the embodiments described above and illustrated by the drawings. For example, the following embodiments will be included in the technical scope.

(1) In the above embodiment, the alignment film formation process is performed after the second dry-cleaning process. However, the technology described herein is not limited to this example. A film formation process other than the alignment film formation process may be performed after the second dry-cleaning process.

(2) The wet cleaning and the dry cleaning are not limited to those described in the above embodiment.

(3) In the above embodiment, the dry cleaning using excimer UV is performed in the first dry-cleaning process and the second dry-cleaning process. However, the technology described herein is not limited to this example. For example, the dry cleaning using excimer UV may be performed in the first dry-cleaning process (in the treatment tank 41) and the dry cleaning using atmospheric-pressure plasma may be performed in the second dry-cleaning process (in the treatment tank 44), and vice versa. Alternatively, the dry cleaning using atmospheric-pressure plasma may be performed in the first and second dry-cleaning process.

1. A method of producing a liquid crystal panel, the method comprising:
a first dry-cleaning process of dry cleaning a glass substrate for a liquid crystal panel;
a wet-cleaning process of wet cleaning the glass substrate after the first dry-cleaning process; and
a second dry-cleaning process of dry cleaning the glass substrate after the wet-cleaning process.

2. The method of producing a liquid crystal panel according to claim 1, wherein the dry cleaning uses one of atmospheric-pressure plasma and excimer UV.

3. The method of producing a liquid crystal panel according to claim 1, further comprising an alignment film formation process of forming; an alignment film on a surface of the glass substrate after the second dry-cleaning process.

4. The method of producing a liquid crystal panel according to claim 3, wherein the alignment film formation process is performed within 600 seconds from end of the second dry-cleaning process.
